(19) United States
(12) Patent Application Publication
(10) Pub. No.: US 2002/0190314 A1
(43) Pub. Date: Dec. 19, 2002

(54) Methods for manufacturing semiconductor devices and semiconductor devices

(76) Inventor: Kazunobu Kuwazawa, Sakata-shi (JP)

Correspondence Address: KONRAD RAYNES VICTOR & MANN, LLP, 315 SOUTH BEVERLY DRIVE, SUITE 210, BEVERLY HILLS, CA, 90212, US

(21) Appl. No.: 09/885,761

(22) Filed: Jun. 19, 2001

(30) Foreign Application Priority Data
Jun. 19, 2001 (JP) 2000-182847

(51) Int. Cl. H01L 21/336; H01L 29/76; H01L 29/94; H01L 31/062; H01L 31/113; H01L 31/119

(52) U.S. Cl. 257/336; 438/305; 257/344; 438/301

(57) ABSTRACT

Embodiments include methods for manufacturing semiconductor devices and semiconductor devices in which an extension region, a source region and a drain region can be simultaneously formed. One method for manufacturing a semiconductor device includes (a) forming a gate dielectric layer 20 over a semiconductor substrate 10; (b) forming a gate electrode 22 over the gate dielectric layer 20; (c) forming an extension control layer 40 over the semiconductor substrate 10 on sides of the gate dielectric layer 20; and (d) forming a source region 24 and a drain region 26 by ion-implanting an impurity 80 in the semiconductor substrate 10, wherein an extension region 30 is formed in the semiconductor substrate 10 below the extension control layer 40 with the source region 24 and the drain region 26.

Applicants hereby incorporate by reference Japanese Application No. 2000-182847, filed Jun. 19, 2000, in its entirety.

### TECHNICAL FIELD

The present invention relates to methods for manufacturing semiconductor devices and semiconductor devices, and more particularly, to methods for manufacturing semiconductor devices having a field effect type transistor and such semiconductor devices.

### BACKGROUND

In recent years, a technique for forming extension regions 130 in a semiconductor substrate 110 between a gate dielectric layer 120 and source/drain regions 124 and 126 in a MOS transistor 200 shown in FIG. 5 has been proposed.

For example, the MOS transistor 200 having the extension regions 130 is formed in the following manner. FIG. 6 schematically shows a cross-sectional view in a process for manufacturing a MOS transistor having extension regions in the conventional art.

First, as shown in FIG. 6(a), a gate oxide film 120 and a gate electrode 122 are formed over a semiconductor substrate 110. Then, an impurity is ion-implanted in the semiconductor substrate 110 using the gate electrode 122 as a mask to thereby form extension regions 130 in the semiconductor substrate 110 on both sides of the gate electrode 122.

Then, as shown in FIG. 6(b), a dielectric layer 172 is deposited over the entire surface of the semiconductor substrate 110. Then, as shown in FIG. 5, the dielectric layer 172 is etched by RIE (reactive ion etching), to form sidewall spacers 170 on sidewalls of the gate electrode 122. Then, an impurity is ion-implanted in the semiconductor substrate 110 using the gate electrode 122 and the sidewall spacers 170 as a mask to form source/drain regions 124 and 126. In this manner, the MOS transistor 200 having the extension regions 130 shown in FIG. 5 is formed.

It is noted that, in the above-described technique, the dielectric layer 172 is deposited in order to form the sidewall spacer 170. The dielectric layer 172 is deposited under high-temperature conditions. For example, when the dielectric layer 172 is formed from a silicon nitride film, the silicon nitride film is deposited under a condition at about 750° C. As a result, when the dielectric layer 172 is deposited, the extension regions 130 are diffused into the substrate and the boundary of the extension regions moves in the directions of the arrows from the dotted line 181 to the line 183 as indicated in FIG. 6(b). As the extension regions 130 are diffused, control of the extension regions 130 becomes difficult, and this may lead to an increased resistance value of the extension regions 130.

### SUMMARY

Embodiments include a method for manufacturing a semiconductor device, the method including forming a gate dielectric layer over a semiconductor substrate and forming a gate electrode over the gate dielectric layer. The method also includes forming an extension control layer over the semiconductor substrate on sides of the gate dielectric layer. The method also includes forming a first impurity layer and a second impurity layer by ion-implanting an impurity in the semiconductor substrate, wherein an extension region is formed in the semiconductor substrate below the extension control layer during the ion-implanting used to form the first impurity layer and the second impurity layer.

Embodiments also include a semiconductor device including a gate dielectric layer provided over a semiconductor substrate and a gate electrode provided over the gate dielectric layer. The device also includes a first impurity layer and a second impurity layer provided in the semiconductor substrate on sides of the gate dielectric layer. The device also includes an extension region provided in the semiconductor substrate between the gate dielectric layer and at least one of the first impurity layer and the second impurity layer. In addition, an extension control layer is provided over the extension region.

Embodiments also include a method for manufacturing a semiconductor device including extension regions and source/drain regions formed using a single ion-implantation step, the method including forming a gate dielectric layer over a semiconductor substrate and forming a gate electrode over the gate dielectric layer. The method also includes forming extension control structures over a portion of the semiconductor substrate next to the gate dielectric layer. The method also includes a single ion-implanting step that forms extension regions in the semiconductor substrate under the extension control structures and source/drain regions in the semiconductor substrate adjacent to the extension layer, wherein the extension regions have a depth that is less than that of the source/drain regions.

### BRIEF DESCRIPTION OF THE DRAWINGS

Embodiments of the invention are described with reference to the accompanying drawings which, for illustrative purposes, are schematic and not necessarily drawn to scale.

FIG. 1 schematically shows a cross-sectional view of a semiconductor device in accordance with an embodiment of the present invention.

FIG. 2 schematically shows cross-sectional views in a process for manufacturing a semiconductor device in accordance with an embodiment of the present invention.

FIG. 3 schematically shows cross-sectional views in the process for manufacturing a semiconductor device in accordance with an embodiment of the present invention.

FIG. 4 schematically shows cross-sectional views in the process for manufacturing a semiconductor device in accordance with an embodiment of the present invention.

FIG. 5 schematically shows a cross-sectional view of a conventional MOS transistor having extension regions in one example.

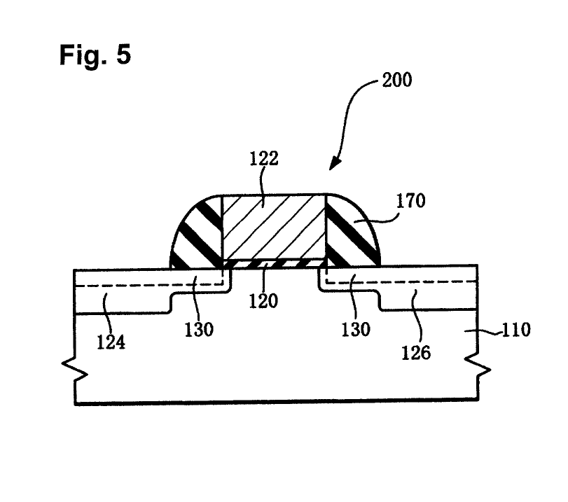

FIG. 6 schematically shows cross-sectional views of a MOS transistor having extension regions in a conventional manufacturing method in one example.

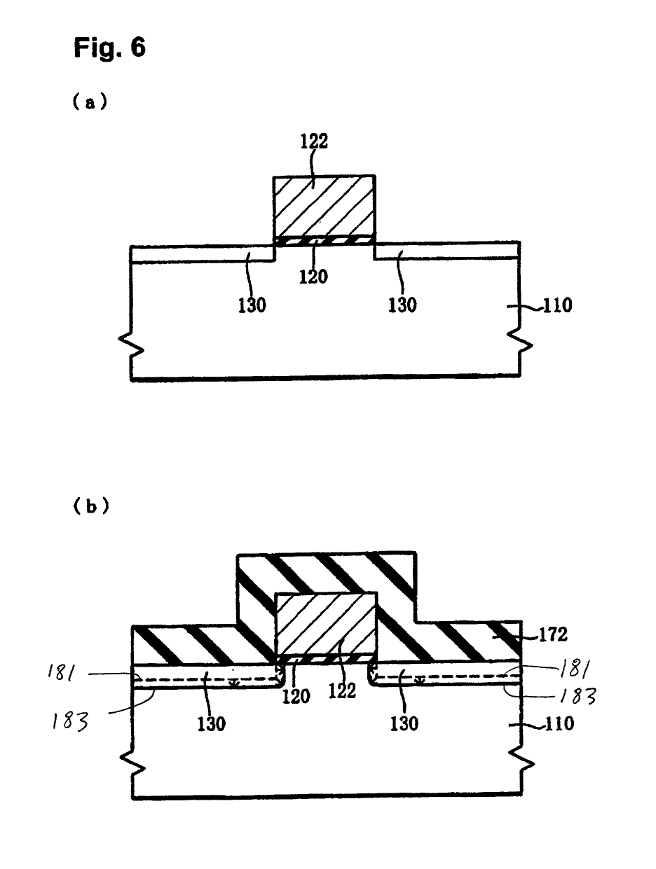

### DETAILED DESCRIPTION

It is an object of certain embodiments of the present invention to provide methods for manufacturing semiconductor devices and semiconductor devices in which an extension region, a source region and a drain region can be simultaneously formed.

In accordance with one embodiment of the present invention, a method for manufacturing a semiconductor device includes the steps of: (a) forming a gate dielectric layer over a semiconductor substrate; (b) forming a gate electrode over the gate dielectric layer; (c) forming an extension control layer over the semiconductor substrate on sides of the gate dielectric layer; and (d) forming a first impurity diffusion layer and a second impurity diffusion layer by ion-implanting an impurity in the semiconductor substrate, wherein an extension region is formed in the semiconductor substrate below the extension control layer with the first impurity diffusion layer and the second impurity diffusion layer.

It is noted that the “extension control layer” is a layer such as a dielectric layer that controls conditions of the impurity implanted in a region where the extension region is formed so that the extension region has the designed characteristics (for example, depth, concentration) in the step (d).

In accordance with the present embodiment, the extension control layer is formed on sides of the gate electrode. As a result, by controlling the film thickness or the material of the extension control layer, the extension region may be formed simultaneously with the first and second impurity diffusion layers under the ion-implantation condition for forming the first and second impurity diffusion layers. As a result, after the extension region is formed, sidewall spacers to define the first and second impurity diffusion layers do not need to be formed. As a result, diffusion of the extension region is suppressed, and an increase in the resistance value of the extension region is suppressed. Accordingly, in accordance with the present embodiment, a semiconductor device having an improved transistor performance can be obtained. Also, by controlling the film thickness and the material of the extension control layer, an extension region having required characteristics can be formed.

Preferably, the step (c) may further include the step of forming a sidewall protection film on sidewalls of the gate electrode with the extension control layers. By forming the sidewall protection film on the sidewalls of the gate electrode, the sidewalls of the gate electrode is prevented from reacting with various materials in the succeeding steps.

When the sidewall protection film is formed in the step (c), the step (c) may further include the steps of: (c-1) forming a dielectric layer over the semiconductor substrate; (c-2) forming a sidewall mask layer on sides of the gate electrode over the dielectric layer; (c-3) removing the dielectric layer using the sidewall mask layer as a mask to form the extension control layer and the sidewall protection layer; and (c-4) removing the sidewall mask layer after the step (c-3).

In other words, by removing the dielectric layer using the sidewall mask layer as a mask, the extension control layer and the sidewall protection film are formed. In the formation of the sidewall mask layer, a photolithography step is not required to form the sidewall mask layer. Accordingly, by the inclusion of the steps (c-1) through (c-4) in the step (c), the extension control layer and the sidewall protection layer may be formed without including a photolithography step.

The material of the extension control layer may be formed from, for example, silicon nitride. In this case, the sidewall mask layer may preferably be formed from silicon oxide. Another example of a material for the extension control layer is silicon oxide. In this case, the sidewall mask layer may preferably be formed from silicon nitride.

The thickness of the extension control layer may be defined in view of the required characteristics of the extension region, and may be, for example, 5-50 nm. The sidewall mask layer may have a thickness of, for example, 30-200 nm upon film formation thereof.

A semiconductor device that is obtained by the method for manufacturing a semiconductor device of the present invention described above may include, for example, the following embodiment.

Such a semiconductor device comprises: a gate dielectric layer provided over a semiconductor substrate; a gate electrode provided over the gate dielectric layer; a first impurity diffusion layer and a second impurity diffusion layer provided in the semiconductor substrate on sides of the gate dielectric layer; an extension region provided in the semiconductor substrate between the gate dielectric layer and at least one of the first impurity diffusion layer and the second impurity diffusion layer; and an extension control layer provided over the extension region.

The semiconductor device described above may further include a sidewall protection film formed on sidewalls of the gate electrode. The sidewall protection film may preferably be continuous with the extension control layer. In this case, the extension control layer and the sidewall protection film may preferably define a substantially L-shaped cross-sectional configuration.

The extension control layer is formed from, for example, silicon nitride or silicon oxide. The extension control layer has a thickness of 5-50 nm, for example.

Preferred embodiments of the present invention will be described below in accordance with the drawings.

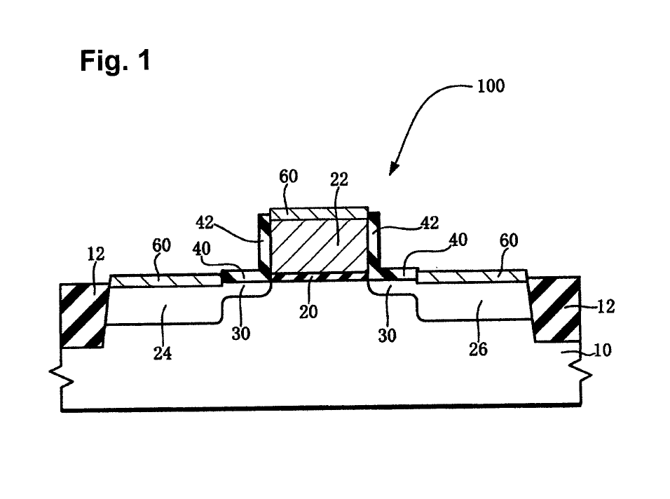

A semiconductor device in accordance with an embodiment of the present invention is described below. FIG. 1 schematically shows a cross-sectional view of a semiconductor device in accordance with the embodiment. A semiconductor device 100 has a semiconductor substrate 10 in which an element region is defined by trench element isolation regions 12. A gate dielectric layer 20 is formed over the semiconductor substrate 10. A gate electrode 22 is formed over the gate dielectric layer 20. On one side of the gate dielectric layer 20, a source region 24 is formed in the semiconductor substrate 10. On the other side of the gate dielectric layer 20, a drain region 26 is formed in the semiconductor substrate 10. An extension region 30 is formed between the gate dielectric layer 20 and the source region 24. Also, an extension region 30 is formed between the gate dielectric layer 20 and the drain region 26.

Extension control layers 40 are formed over the extension region 30. Sidewall protection films 42 are formed on sidewalls of the gate electrode 22. The sidewall protection films 42 are preferably continuous with the extension control layers 40. Also, a cross-sectional configuration that is formed by the extension control layer 40 and the sidewall protection film 42 is preferably in the shape of a letter “L”. While illustrated in FIG. 1 as having an precise L shape with straight line surfaces, it should be appreciated that the extension control layer 40 and sidewall protection film 42 (as well as other structures in or on the substrate 10) may have a variety of shapes and may have surfaces that are somewhat curved due to, for example, deposition and etching processes.

A silicide layer 60 is preferably formed over an upper surface of the gate electrode 22. Furthermore, silicide layers 60 are also preferably formed over the surface of the semiconductor substrate 10 in the source region 24 and the drain region 26.

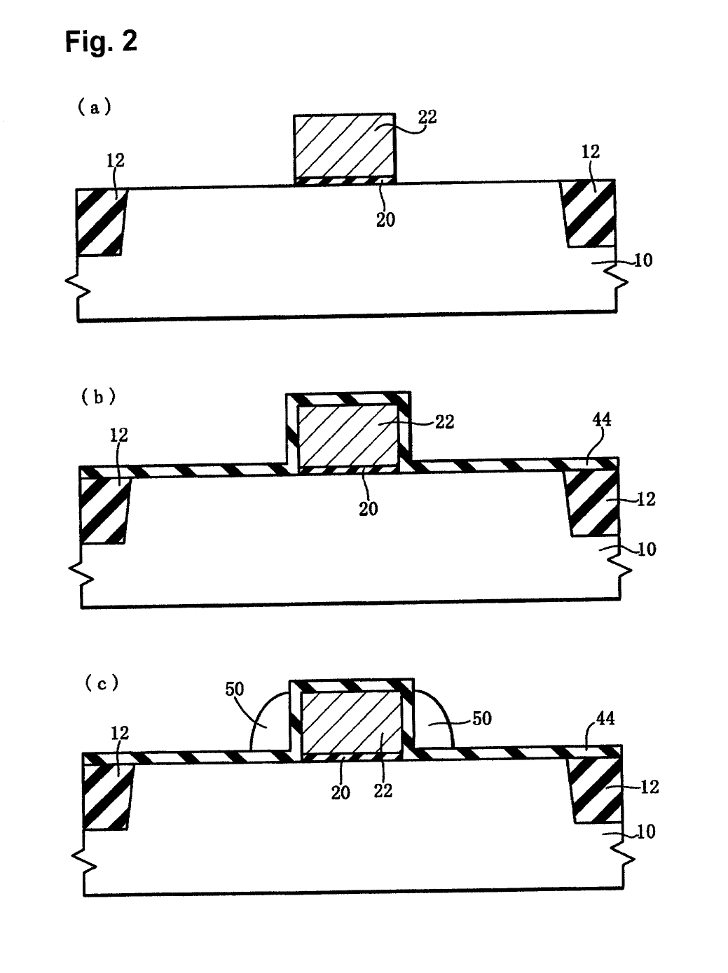

A method for manufacturing a semiconductor device in accordance with an embodiment of the present invention is described below. FIG. 2 through FIG. 4 schematically show cross-sectional views in a process for manufacturing a semiconductor device in accordance with the present embodiment.

First, as shown in FIG. 2(a), trench element isolation regions 12 are preferably formed in a semiconductor substrate 10 of silicon by a known method. A gate dielectric layer 20 and a gate electrode 22 that is formed from polysilicon are formed over the semiconductor substrate 10 by a known method. Then, depending on the requirements, the semiconductor substrate 10 and the gate electrode 22 may be subjected to a sacrificial oxidation.

Then, as shown in FIG. 2(b), a silicon nitride layer 44 is formed over the semiconductor substrate 10. The silicon nitride layer 44 later becomes an extension control layer 40 and a sidewall protection film 42. The film thickness of the silicon nitride layer 44 may vary depending on the required characteristics of extension regions 30, and may be, for example, 5-50 nm. The silicon nitride layer 44 may be formed by, for example, a CVD method.

Then, as shown in FIG. 2(c), sidewall mask layers 50 are formed on sides of the gate electrode 22. For example, the sidewall mask layers 50 may be formed in the following manner. A silicon oxide film is formed over the entire surface by a CVD method. The thickness of the silicon oxide film is, for example, 30-200 nm. Then, the silicon oxide film is anisotropically etched by a reactive ion etching or the like to form the sidewall mask layers 50. The sidewall mask layers 50 function as a mask when the silicon nitride layer 44 is etched. The material of the sidewall mask layers 50 is not limited to the silicon oxide film as long as it can achieve its intended function.

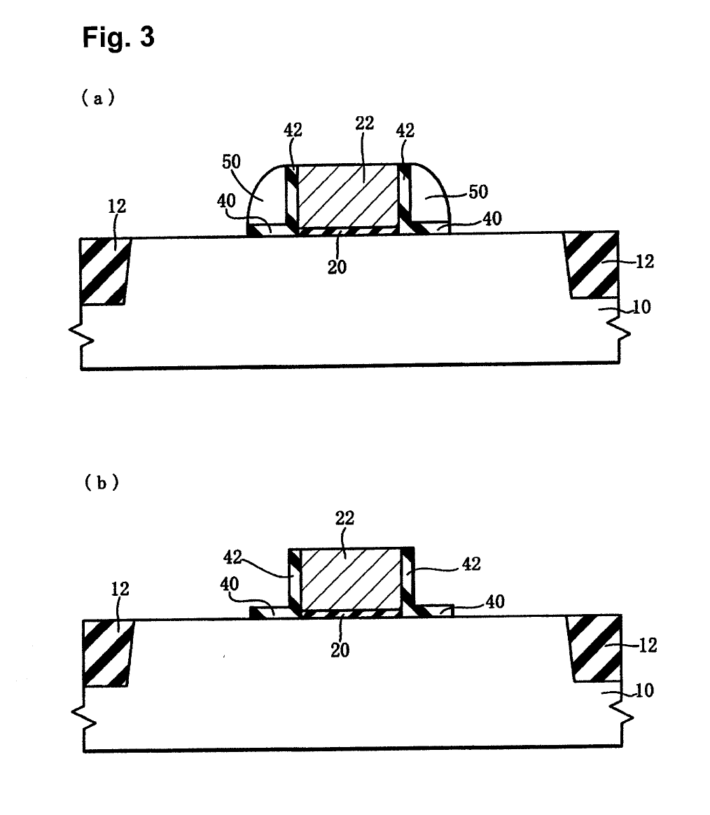

Then, as shown in FIG. 3(a), the silicon nitride layer 44 is etched using the sidewall mask layers 50 as a mask. As a result, extension control layers 40 are formed over the semiconductor substrate 10 on sides of the gate electrode 22. Also, at the same time, sidewall protection films 42 are formed on sidewalls of the gate electrode 22. The silicon nitride layer 44 may be etched by an isotropic etching using heated phosphoric acid.

Then, as shown in FIG. 3(b), the sidewall mask layers are removed by etching.

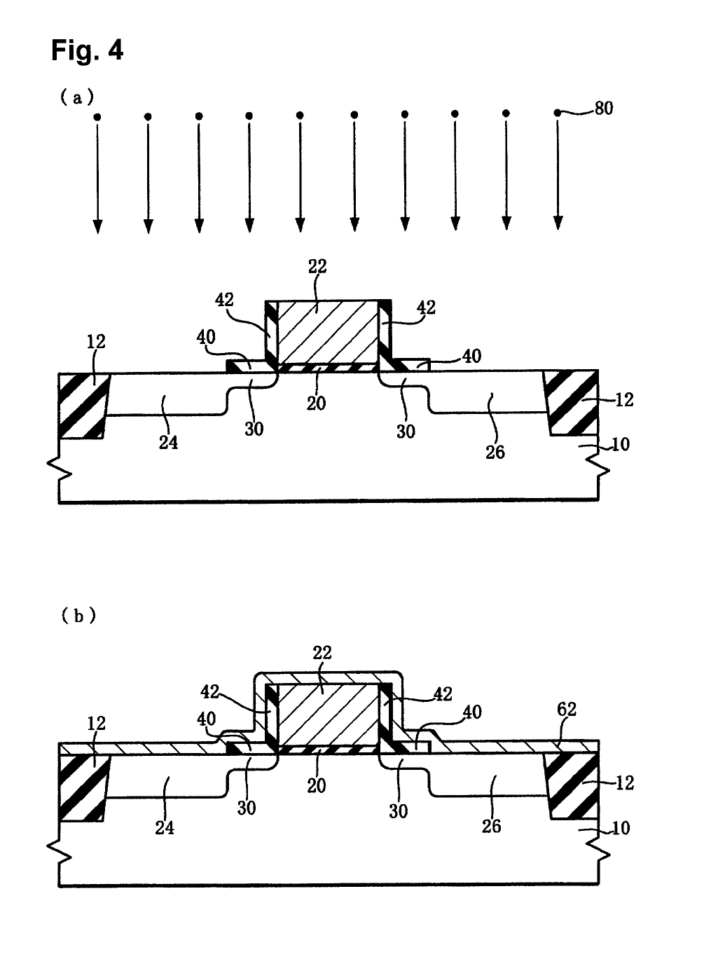

Then, as shown in FIG. 4(a), an impurity 80 is ion-implanted in the semiconductor substrate 10 to thereby simultaneously form source/drain regions 24 and 26 and extension regions 30. The ion implantation can be conducted under the condition in which the source/drain regions 24 and 26 are formed. Here, the extension control layers 40 are formed over the semiconductor substrate 10 in regions where the extension regions 30 are to be formed.

Accordingly, as for the impurity implanted in regions where the extension regions are to be formed, its energies are absorbed by the extension control layers 40 or a part of the impurity is trapped by the extension control layers 40. In other words, the extension control layers 40 can control the conditions of the impurity that is to be implanted in the region wherein the extension regions 30 are formed. As a result, by controlling the film thickness of the extension control layers 40, the extension regions 30 having the required characteristics can be formed simultaneously when the source/drain regions 24 and 26 are formed. In other words, the depth of the extension regions 30 and the impurity concentration of the extension regions 30 can be controlled by varying the film thickness of the extension control layers 40.

For example, the conditions for forming the source/drain regions can be employed as conditions for the ion-implantation. For example, in the case of an N-type transistor, and when the impurity is arsenic, the energy is, for example, 30-100 kev, and more preferably, 50-70 kev; and the dose is, for example, 5e14-1e16 cm⁻², and more preferably, 1e15-5e15 cm⁻². On the other hand, in the case of a P-type transistor, and when the impurity is boron, the energy is, for example, 5-15 kev, and more preferably, 8-10 kev; and the dose is, for example, 5e14-1e16 cm⁻², and more preferably, 1e15-5e15 cm⁻².

Then, depending on the requirements, the semiconductor substrate 10 may be subjected to an annealing process. By conducting the annealing process, crystal defects in the semiconductor substrate 10 in which the impurity 80 is implanted can be repaired. The process temperature of the annealing process is determined in view of the diffusion of the extension regions 30, and may be, for example, 1000 to 1100° C. The time for the annealing process is determined in view of the processing temperatures, and may be, for example, 1 to 10 seconds.

Then, as shown in FIG. 4(b), a metal layer 62 for forming a silicide layer 60 is formed over the semiconductor substrate 10 including the gate electrode 22. Here, the sidewall protection films 42 function to prevent the sidewalls of the gate electrode 22 from becoming silicide. Also, the extension control layers 40 function to prevent the surface of the semiconductor substrate 10 in the extension regions 30 from becoming silicide. The metal layer 62 may be formed by, for example, a CVD method or a sputtering method. The metal layer 62 may be formed from a material, such as, for example, titanium, cobalt or nickel.

Then, as shown in FIG. 1, a heat treatment may be conducted to form silicide layers 60 on upper portions of the source/drain regions 24 and 26 and the gate electrode 22. The temperature of the heat treatment is determined in view of the diffusion of the extension regions 30, and may be, for example, 450-550° C. in the case of cobalt. Then, the metal layer 62 that has not become silicide is removed to complete the semiconductor device 100 shown in FIG. 1.

In the present embodiment, the extension control layers 40 are formed. As a result, by controlling the film thickness of the extension control layers 40, the extension regions 30 having required characteristics can be formed simultaneously when the source/drain regions 24 and 26 are formed. For example, by controlling the film thickness of the extension control layers 40, the extension regions 30 having a concentration similar to a concentration of the source/drain regions 24 and 26, or the extension regions 30 that can function as LDD regions, can be formed.

In accordance with the present embodiment, the extension regions 30 and the source/drain regions 24 and 26 are simultaneously formed. As a result, unlike the conventional method, a process in which, after the extension regions 30 are formed, sidewall spacers are formed on sides of the gate electrode, and the source/drain regions are formed, does not have to be conducted. As a result, after the extension regions 30 are formed, the step of forming a dielectric layer for sidewall spacers to be conducted under a high-temperature condition does not need to be conducted. Therefore, thermal diffusion of the extension regions 30 can be suppressed. Accordingly, in accordance with the present embodiment, an increase in the resistance value of the extension regions 30 can be suppressed, and the transistor performance can be improved.

In accordance with the present environment, the extension regions 30 and the source/drain regions can be formed by conducting an ion-implantation of an impurity once.

Also, in accordance with the present embodiment, the silicon nitride layer 44 is etched by using the sidewall mask layers 50 as a mask to form the extension control layers 40 and the sidewall protection layers 42. When the sidewall mask layers 50 are formed, a photolithography step to form the sidewall mask layers 50 is not required. Therefore, in accordance with the present embodiment, the extension control layers 40 and the sidewall protection films 42 can be formed without including a photolithography step.

The present invention is not limited to the embodiments described above, and many modifications can be made within the scope of the subject matter of the invention. For example the following modifications can be made.

In the embodiment described above, the extension control layers 40 and the sidewall protection films 42 are formed from silicon nitride layers. However, the extension control layers 40 and the sidewall protection films 42 are not limited to this embodiment, and may be formed from other materials, such as silicon oxide layers. Also, when the extension control layers 40 and the sidewall protection films 42 are formed from silicon oxide layers, the sidewall mask layers 50 can be formed from other materials, such as silicon nitride.

What is claimed:

1. A method for manufacturing a semiconductor device, the method comprising:
(a) forming a gate dielectric layer over a semiconductor substrate;
(b) forming a gate electrode over the gate dielectric layer;
(c) forming an extension control layer over the semiconductor substrate on sides of the gate dielectric layer; and
(d) forming a first impurity layer and a second impurity layer by ion-implanting an impurity in the semiconductor substrate,
wherein an extension region is formed in the semiconductor substrate below the extension control layer during the ion-implanting used to form the first impurity layer and the second impurity layer.

2. A method for manufacturing a semiconductor device according to claim 1, wherein the step (c) further includes the step of forming a sidewall protection film on sidewalls of the gate electrode with the extension control layers.

3. A method for manufacturing a semiconductor device according to claim 2, wherein the step (c) further includes the steps of:
(c-1) forming a dielectric layer over the semiconductor substrate;
(c-2) forming a sidewall mask layer on sides of the gate electrode over the dielectric layer;
(c-3) removing the dielectric layer using the sidewall mask layer as a mask to form the extension control layer and the sidewall protection layer; and
(c-4) removing the sidewall mask layer after the step (c-3).

4. A method for manufacturing a semiconductor device according to claim 3, wherein the extension control layer is formed from a material comprising silicon nitride.

5. A method for manufacturing a semiconductor device according to claim 4, wherein the sidewall mask layer is formed from a material comprising silicon oxide.

6. A method for manufacturing a semiconductor device according to claim 3, wherein the extension control layer is formed from a material comprising silicon oxide.

7. A method for manufacturing a semiconductor device according to claim 6, wherein the sidewall mask layer is formed from a material comprising silicon nitride.

8. A method for manufacturing a semiconductor device according to claim 1, wherein the extension control layer has a thickness of 5-50 nm.

9. A method for manufacturing a semiconductor device according to claim 3, wherein the sidewall mask layer is formed to a thickness of 30-200 nm.

10. A semiconductor device comprising:
a gate dielectric layer provided over a semiconductor substrate;
a gate electrode provided over the gate dielectric layer;
a first impurity layer and a second impurity layer provided in the semiconductor substrate and spaced away from sides of the gate dielectric layer;
an extension region provided in the semiconductor substrate between the gate dielectric layer and at least one of the first impurity layer and the second impurity layer; and
an extension control layer provided over the extension region.

11. A semiconductor device according to claim 10, further comprising a sidewall protection film formed on sidewalls of the gate electrode.

12. A semiconductor device according to claim 11, wherein the sidewall protection film comprises silicon oxide and the extension control layer comprises silicon nitride.

13. A semiconductor device according to claim 11, wherein the sidewall protection film comprises silicon nitride and the extension control layer comprises silicon oxide.

14. A semiconductor device according to claim 11, wherein the sidewall protection film is integral with the extension control layer.

15. A semiconductor device according to claim 11, wherein the extension control layer and the sidewall protection film define a substantially L-shaped cross-sectional configuration.

16. A semiconductor device according to claim 10, wherein the extension control layer comprises silicon nitride.

17. A semiconductor device according to claim 10, wherein the extension control layer comprises silicon oxide.

18. A semiconductor device according to claim 10, wherein the extension control layer ha s a thickness of 5-50 nm.

19. A semiconductor device according to claim 10, wherein the extension region includes portions provided in the semiconductor substrate between the gate dielectric layer and both the first impurity layer and the second impurity layer.

20. A semiconductor device according to claim 19, further comprising a sidewall protection film on sidewalls of the gate electrode, wherein the extension control layer and sidewall protection film form a substantially L-shaped structure in cross section on at least one side of the gate dielectric layer.

21. A method for manufacturing a semiconductor device including extension regions and source/drain regions formed using a single ion-implantation step, the method comprising:
forming a gate dielectric layer over a semiconductor substrate;
forming a gate electrode over the gate dielectric layer;
forming extension control structures over a portion of the semiconductor substrate next to the gate dielectric layer; and
a single ion-implanting step that forms extension regions in the semiconductor substrate under the extension control structures and source/drain regions in the semiconductor substrate adjacent to the extension layer, wherein the extension regions have a depth that is less than that of the source/drain regions.

22. A method according to claim 21, further comprising forming sidewall protection structures on sidewalls of the gate electrode, wherein the sidewall protection structures are formed from the same material as the extension control structures.

23. A method according to claim 22, wherein the extension control structures and sidewall protection structures are formed using a method comprising:
depositing a dielectric layer over the surface of the semiconductor substrate and the gate electrode;
forming a mask layer on the dielectric layer;
anisotropically etching the mask layer to form a sidewall mask layer;
etching the dielectric layer using the sidewall mask layer as a mask so that the dielectric layer remains at sidewalls of the gate electrode and extends a distance outward from the gate dielectric layer along the surface of the dielectric layer; and
removing the sidewall mask layer;
wherein the dielectric layer remaining at sidewalls of the gate electrode defines the sidewall protection structures and the dielectric layer extending a distance outward from the gate dielectric layer along the surface of the dielectric layer defines the extension control structures.

24. A method of manufacturing a semiconductor device according to claim 1, wherein the extension control layer is formed from a dielectric material.
